(19) United States
(12) Patent Application Publication
(10) Pub. No.: US 2026/0244228 A1
(43) Pub. Date: Aug. 20, 2026

(54) REMOTE TEMPERATURE SENSOR CIRCUIT AND METHOD

(71) Applicant: TAIWAN SEMICONDUCTOR MANUFACTURING COMPANY, LTD., Hsinchu (TW)

(72) Inventors: Szu-Lin LIU, Hsinchu (TW); Bei-Shing LIEN, Hsinchu (TW)

(21) Appl. No.: 19/247,150

(22) Filed: Jun. 24, 2025

Related U.S. Application Data
(60) Provisional application No. 63/760,922, filed on Feb. 20, 2025.

(51) Int. Cl. G05D 23/19; G05D 23/24

(52) U.S. Cl. CPC G05D 23/1934; G05D 23/1917; G05D 23/24

(57) ABSTRACT

A circuit includes a parallel arrangement of a resistive device and a switching device, a current path including a first end coupled to a first terminal of the parallel arrangement, a current source configured to output a current, a switching circuit coupled between a second end of the current path and the current source, and a voltage sensing circuit including an output terminal and an input terminal coupled to the switching circuit. The circuit is configured to output a signal at the voltage sensing circuit output terminal based on a first voltage level output from the switching circuit concurrently with the current path conducting the current and the switching device being in an open state, and a second voltage level output from the switching circuit concurrently with the current path conducting the current and the switching device being in a closed state.

### PRIORITY CLAIM

The present application claims the priority of U.S. Provisional Application No. 63/760,922, filed Feb. 20, 2025, which is incorporated herein by reference in its entirety.

### BACKGROUND

In many integrated circuit (IC) applications, e.g., high speed digital circuits, the heat generated during circuit operation can become significant with respect to operating parameters or circuit reliability. Such circuits often include one or more specific locations, e.g., hot spots, at which circuit activity can generate temperature increases large enough to affect circuit performance. Temperature sensors that monitor temperature increases at these locations are sometimes employed so that circuit activity can be modified in response.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are a respective block diagram and schematic diagram of a temperature measurement circuit, in accordance with some embodiments.

FIG. 2 is a schematic diagram of a temperature sensor circuit, in accordance with some embodiments.

FIG. 3 is a schematic diagram of a calibration circuit, in accordance with some embodiments.

FIG. 4 is a schematic diagram of a comparator, in accordance with some embodiments.

FIG. 5 is a schematic diagram of a sampling stage, in accordance with some embodiments.

FIG. 6 is a timing diagram of a temperature sensor circuit, in accordance with some embodiments.

FIG. 7 is a schematic diagram of a temperature sensor circuit, in accordance with some embodiments.

FIG. 8 is a flowchart of a method of operating a circuit, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a circuit and method include a current source and voltage sensing circuit electrically connected through a current path and a switching circuit to at least one temperature sensing device (TSD) that includes a parallel arrangement of a temperature-sensitive resistive device and a switching device. The circuit is configured to output a signal, e.g., from an analog-to-digital converter (ADC) of the voltage sensing circuit, based on one voltage level detected while the current path conducts the current and the switching device is in a closed state, thereby also conducting the current, and another voltage level detected while the current path conducts the current and the switching device is in an open state, thereby causing the resistive device to also conduct the current.

Because one voltage level represents the voltage drop based on the parasitic resistance of the current path, and the other voltage level represents the total voltage drop including both the resistive device and the parasitic resistance, the difference between the two voltage levels can be used to obtain an accurate measurement of the resistance of the resistive device, and thereby the temperature of the TSD. In some embodiments, this measurement accuracy is improved by including a calibration resistor configured to be measured using the voltage sensing circuit and the current source.

The circuit is thereby capable of providing remote temperature measurements of one or more targets, e.g., hot spots, close to the one or more TSDs while offsetting the effects of signal path parasitic resistance with reduced complexity compared to other approaches, e.g., those based on beta-dependent bipolar devices or four-terminal Kelvin sensing arrangements.

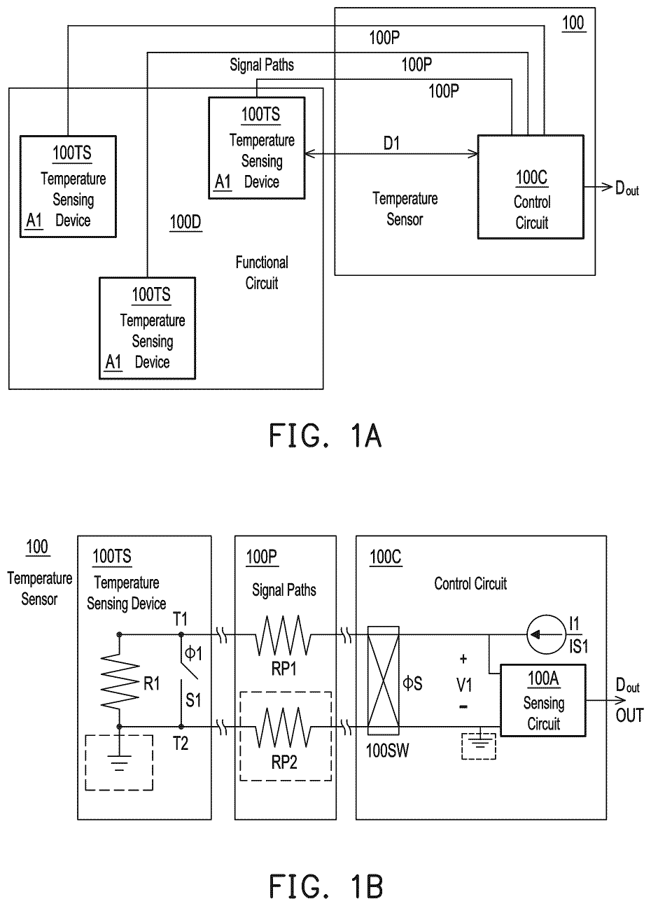

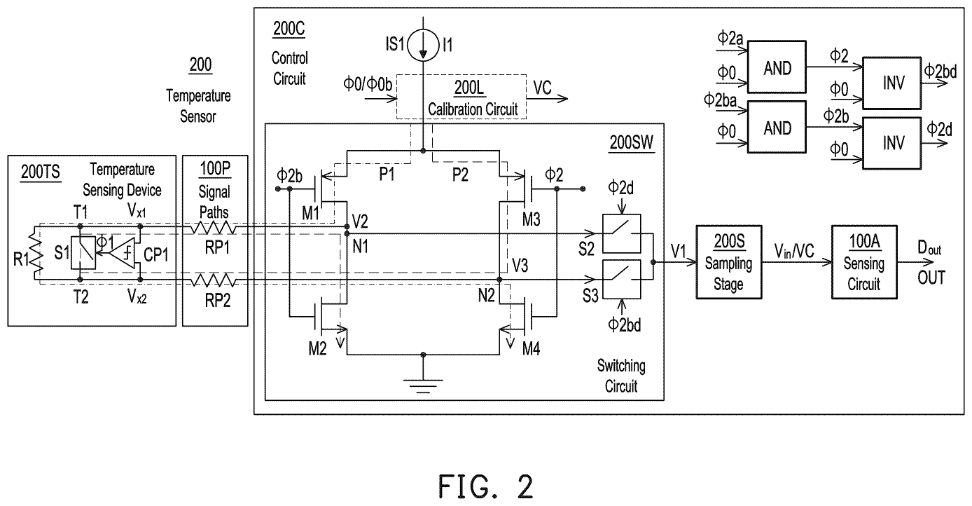

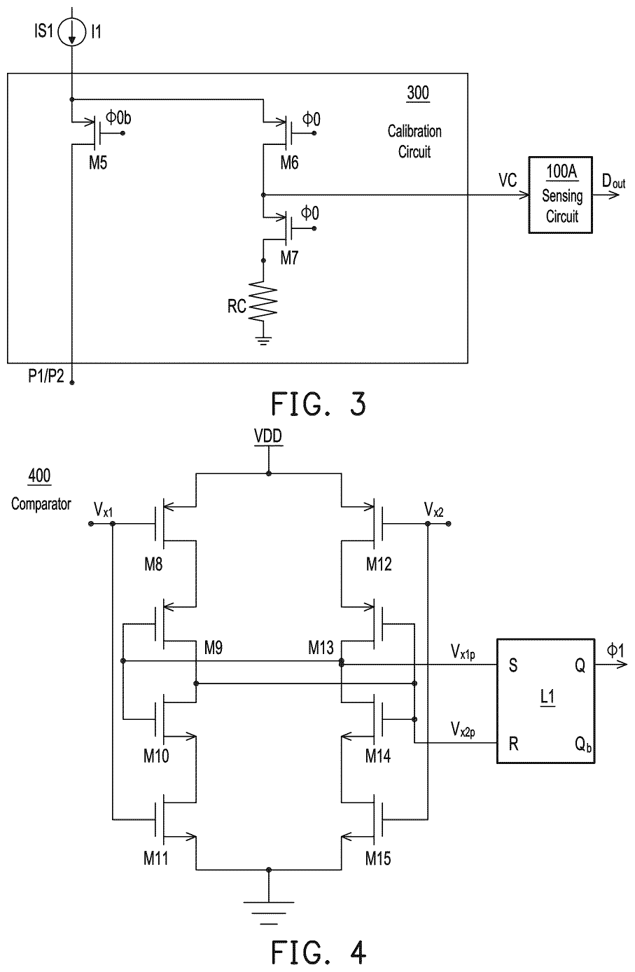

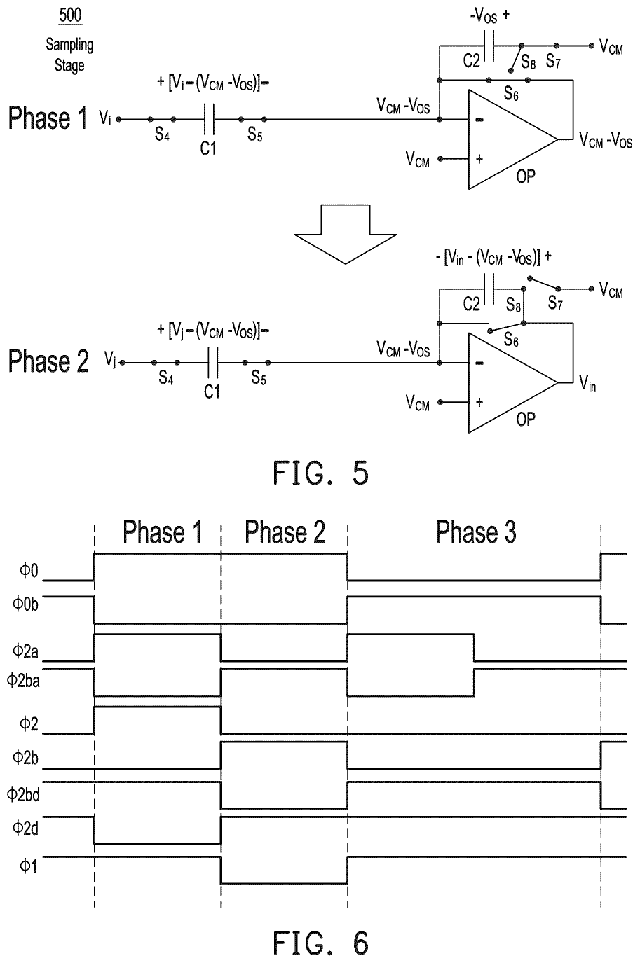

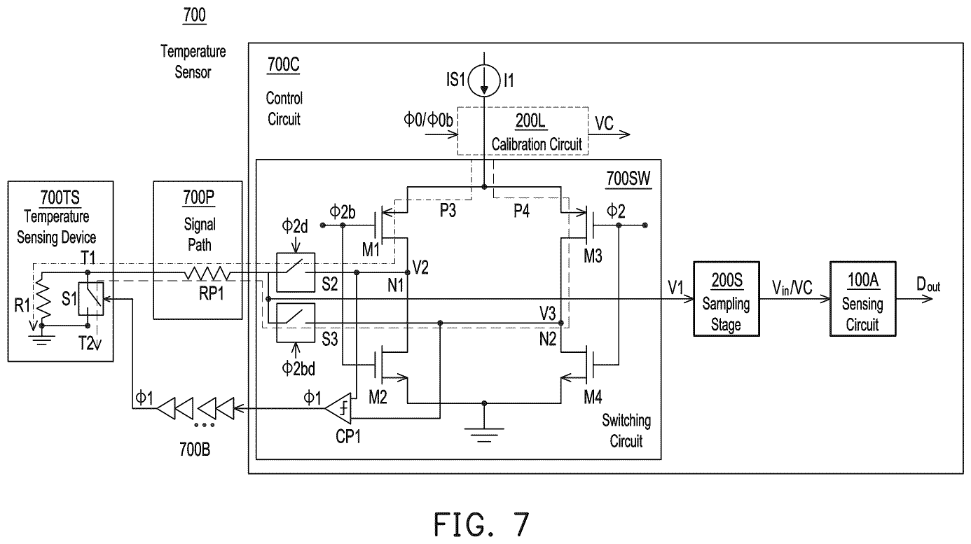

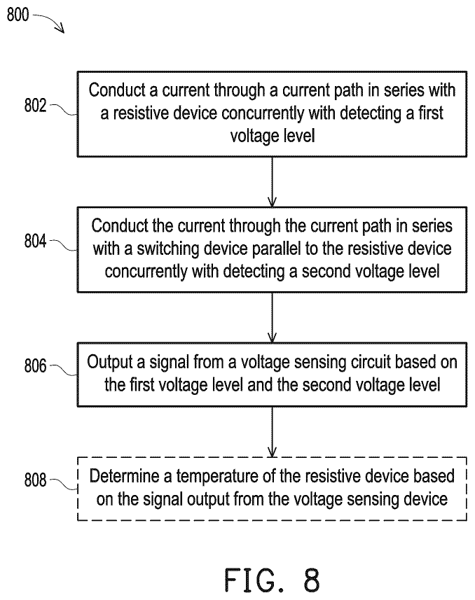

In accordance with various embodiments, FIGS. 1A and 1B are a respective block and schematic diagram of a temperature sensor circuit 100, FIGS. 2 and 7 are schematic diagrams of respective temperature sensor circuits 200 and 700, FIG. 3 is a schematic diagram of a calibration circuit 300 usable in temperature sensor circuits 100, 200, and 700, FIG. 4 is a schematic diagram of a comparator 400 usable in temperature sensor circuits 100, 200, and 700, FIG. 5 is a schematic diagram of a sampling stage 500 usable in temperature sensor circuits 100, 200, and 700, FIG. 6 is a timing diagram of temperature sensor circuit parameters, and FIG. 8 is a flowchart of a method 800 of operating a temperature sensor circuit.

In some embodiments, one or more of temperature sensor circuits 100, 200, or 700 is some or all of an integrated circuit (IC). In some embodiments, one or more of temperature sensor circuits 100, 200, or 700 is included in another IC, e.g., a processor, signal processor, receiver, transmitter, transceiver, or other suitable IC.

FIGS. 1A-5 and 7 are simplified for the purpose of illustration. In some embodiments, one or more of circuits 100-500 or 700 includes features in addition to those depicted in FIGS. 1A-5 and 7, e.g., one or more of a signal generation circuit or power distribution network, that are not depicted for the purpose of clarity. Circuit elements depicted in FIGS. 1A-5 and 7 include corresponding input and output terminals that are not labeled for the purpose of clarity.

FIG. 1A is a block diagram of temperature sensor circuit 100, in accordance with some embodiments. In some embodiments, temperature sensor circuit 100 is referred to as remote temperature sensor (RTSEN) 100, circuit 100, or IC 100.

FIG. 1A depicts a plan view of an IC, e.g., a die or other portion of a semiconductor wafer, including circuit 100 and a circuit 100D. Circuit 100D includes one or more digital or other, e.g., mixed signal, circuits capable of producing heat, e.g., sufficient to potentially affect circuit performance, in operation. Circuit 100 is configured as discussed below to generate a signal Dout, also referred to as output signal Dout in some embodiments, representative of one or more temperatures at one or more locations within circuit 100D.

In the embodiment depicted in FIG. 1A, circuit 100D is electrically isolated from circuit 100. In some embodiments, one or more circuits of circuit 100D are configured to receive signal Dout from circuit 100, e.g., as a temperature feedback or control signal. In some embodiments, circuits 100 and 100D are included in one or more additional circuits (not shown) configured to receive signal Dout from circuit 100, e.g., as a temperature feedback or control signal, as part of the operation of one or more circuits of circuit 100D.

As depicted in FIG. 1A, circuit 100 includes a control circuit 100C, also referred to as central circuit 100C in some embodiments, and three instances of a TSD 100TS located within circuit 100D and electrically coupled to control circuit 100C through corresponding instances of a signal path 100P.

The number and locations of the instances of TSD 100TS depicted in FIG. 1A are non-limiting examples provided for the purpose of illustration. In some embodiments, circuit 100 includes fewer or greater than three instances of TSD 100TS, one or more instances of TSD 100TS are otherwise located with respect to each other and/or control circuit 100C, and/or one or more instances of TSD 100TS are located partially within or adjacent to circuit 100D.

By being located at least partially within or adjacent to a portion of circuit 100D, each instance of TSD 100TS is configured to be thermally coupled to the corresponding portion of circuit 100D and thereby, in operation, have a temperature substantially determined by, e.g., equal to, one or more temperatures of the corresponding portion of circuit 100D.

As the number instances of TSD 100TS increases, the amount of temperature data related to the operation of circuit 100D increases and the complexity and size of circuit 100 also increase.

In some embodiments, circuit 100 includes the number of instances of TSD 100TS ranging from 1 to 50. In some embodiments, circuit 100 includes the number of instances of TSD 100TS ranging from 5 to 40. In some embodiments, circuit 100 includes the number of instances of TSD 100TS ranging from 10 to 30.

Each instance of TSD 100TS occupies an area A1. In some embodiments, each instance of TSD 100TS has a same area A1 size. In some embodiments, one or more instances of TSD 100TS have one or more corresponding area A1 sizes different from one or more area A1 sizes of one or more additional instances of TSD 100TS.

As area A1 size decreases, temperature sensitivity to hot spots in circuit 100D increases as potential circuit configuration options of TSD 100TS decrease.

In some embodiments, area A1 size ranges from 25 square micrometers (μm²) to 200 μm². In some embodiments, area A1 size ranges from 50 μm² to 150 μm². In some embodiments, area A1 size ranges from 75 μm² to 125 μm².

A given instance of TSD 100TS is separated from control circuit 100C by a distance D1 (one instance labeled in FIG. 1A for clarity). In the embodiment depicted in FIG. 1A, the instances of TSD 100TS are separated from control circuit 100C by distance D1 having differing values. In some embodiments, some or all of the instances of TSD 100TS are separated from control circuit 100C by distance D1 having a same value.

Each instance of signal path 100P includes at least one continuous current path, e.g., a signal route, including conductive elements, e.g., copper and/or other suitable metal traces, vias, etc., electrically isolated from surrounding structures, e.g., additional current paths, by one or more insulation layers, e.g., silicon dioxide and/or other suitable dielectric materials.

As a number of current paths increases, a size of signal path 100P increases as a signal carrying capacity also increases. In some embodiments, a given instance of signal path 100P includes a single conduction path, two conduction paths, or more than two current paths.

Each current path of each instance of signal path 100P has a parasitic resistance value that increases as a length of the instance of signal path 100P increases. As the value of distance D1 for a given instance of TSD 100TS increases, the length, and thereby the parasitic resistance value, of each current path of the corresponding instance of signal path 100P increases. Accordingly, as the values of distance D1 corresponding to multiple instances of TSD 100TS increase, the potential coverage area of circuit 100 increases as corresponding parasitic resistance values also increase.

In some embodiments, a given instance of distance D1 has a value ranging from 10 μm to 10 millimeters (mm). In some embodiments, a given instance of distance D1 has a value ranging from 50 μm to 5 mm. In some embodiments, a given instance of distance D1 has a value ranging from 500 μm to 2 mm.

FIG. 1B depicts a single instance of TSD 100TS, a corresponding single instance of signal path 100P, and control circuit 100C. Control circuit 100C includes a switching circuit 100SW, and the instance of TSD 100TS is coupled to switching circuit 100SW through the instance of signal path 100P. In some embodiments, additional instances of TSD 100TS (not shown) are coupled to switching circuit 100SW through corresponding additional instances of signal path 100P (not shown) as discussed above.

TSD 100TS includes a parallel arrangement of a resistive device R1 and a switching device S1 coupled between terminals T1 and T2. In some embodiments, terminal T2 is coupled to a reference voltage, e.g., ground, node (indicated by the ground symbol) configured to carry a reference voltage level, e.g., ground, and provide a current path separate from a current path of the corresponding instance of signal path 100P.

Resistive device R1 is an IC structure that includes a current path between two terminals (corresponding to terminals T1 and T2) having a temperature-sensitive resistance value. In some embodiments, the resistance value increases as the temperature increases. In some embodiments, the resistance value increases linearly with increasing temperature, e.g., over a predefined temperature range.

Resistive device R1 includes one or more materials configured to have the temperature-sensitive resistance value. In some embodiments, the current path of resistive device R1 includes one or more of polycrystalline silicon, a metal, e.g., copper, or one or more other materials suitable for having a temperature-sensitive resistance value.

A switching device, e.g., switching device S1, is an IC device that includes a current path between two terminals, e.g., corresponding to terminals T1 and T2, capable of being switched between an open, e.g., high-resistance, state and a closed, e.g., low-resistance, state responsive to a signal, e.g., an instance of a signal φ1, received at a control terminal (not shown in FIG. 1B).

In some embodiments, switching device S1 includes a field-effect transistor (FET), e.g., a planar device or a FinFET, a transmission gate, or another IC device capable of having open and closed states responsive to the corresponding instance of signal φ1 received at one or more corresponding gates.

Signal path 100P includes two current paths represented as resistors RP1 and RP2, also referred to as parasitic resistances RP1 and RP2 or current paths RP1 and RP2 in some embodiments. Each of resistors RP1 and RP2 corresponds to the parasitic resistance value of the corresponding current path of signal path 100P as discussed above.

Resistor RP1 is coupled between terminal T1 of TSD 100TS and switching circuit 100SW of control circuit 100C, and resistor RP2 is coupled between terminal T2 of TSD 100TS and switching circuit 100SW of control circuit 100C. In some embodiments, e.g., those in which TSD 100TS includes the reference voltage node coupled to terminal T2 as discussed above, signal path 100P does not include resistor RP2.

In addition to switching circuit 100SW, control circuit 100C includes a current source IS1 and a voltage sensing circuit 100A. Current source IS1 includes an output terminal coupled to switching circuit 100SW and, in the embodiment depicted in FIG. 1B, a first input terminal of voltage sensing circuit 100A. In some embodiments, the first input terminal of voltage sensing circuit 100A is coupled to switching circuit 100SW or to a sampling stage, e.g., a sampling stage 200S discussed below with respect to FIGS. 2, 5, and 7, coupled between switching circuit 100SW and voltage sensing circuit 100A.

In some embodiments, e.g., those in which the one or more instances of TSD 100TS include the reference voltage node coupled to terminal T2 as discussed above, control circuit 100C includes the reference voltage node, e.g., coupled to a second input terminal of voltage sensing circuit 100A or included in voltage sensing circuit 100A.

Current source IS1 is an electronic circuit configured to, in operation, receive a power supply voltage (not shown) and output a current I1 from the output terminal to switching circuit 100SW. Current source IS1 is configured to output current I1 having one or more current levels configured to, in operation, generate voltage drops across combinations of resistive device R1, resistor RP1, and/or resistor RP2, capable of being measured by voltage sensing circuit 100A, as discussed below. In some embodiments, current source IS1 is configured to output current I1 having a current level sufficiently small such that a voltage drop across resistors RP1 and RP2 is below a threshold voltage of a transistor, e.g., included in a comparator such as a comparator CP1 discussed below, and sufficiently large such that a voltage drop across resistor device R1 is above the threshold voltage of the transistor.

Voltage sensing circuit 100A is one or more electronic circuits configured to, in operation, detect one or more instances of a voltage level V1 at the first input terminal and output signal Dout on an output terminal OUT based on voltage level V1. In various embodiments, output terminal OUT is considered to be an output terminal of voltage sensing circuit 100A, control circuit 100C, or circuit 100.

In some embodiments, e.g., those in which signal path 100P includes resistor RP2, voltage sensing circuit 100A includes the second input terminal and is configured to, in operation, detect voltage level V1 as a differential voltage based on voltage levels detected at each of the first and second input terminals.

In some embodiments, e.g., those in which signal path 100P does not include resistor RP2, voltage sensing circuit 100A does not include the second input terminal and is configured to, in operation, detect voltage level V1 as the voltage level at the first input terminal relative to the reference voltage level at the reference voltage node.

In some embodiments, voltage sensing circuit 100A includes an ADC and is thereby configured to, in operation, output signal Dout as one or more digital signals having a range of values corresponding to a range of values of the instances of voltage level V1.

In some embodiments, voltage sensing circuit 100A is otherwise configured, e.g., by including one or more analog amplifiers, to output signal Dout as one or more analog signals having a range of values corresponding to the range of values of the instances of voltage level V1.

Switching circuit 100SW is one or more electronic circuits including at least one switching device configured to, in operation, receive one or more signals φS, and responsive to the one or more signals φS, couple current source IS1 and voltage sensing circuit 100A to a selected instance of TSD 100TS through the corresponding instance of signal path 100P.

In some embodiments, e.g., as discussed below with respect to FIGS. 2 and 7, switching circuit 100SW is further configured to, in operation, responsive to the one or more signals φS, selectively couple current source IS1 and voltage sensing circuit 100A to a calibration resistor and/or selectively control a direction of flow of current I1 through the selected instance of TSD 100TS and corresponding instance of signal path 100P.

Circuit 100 is configured to distribute the one or more signals φS to switching circuit 100SW and the one or more instances of signal φ1 to the corresponding instances of switching device S1 in coordination with voltage sensing circuit 100A outputting signal Dout responsive to the instances of voltage level V1.

In some embodiments, circuit 100 includes a controller (not shown), e.g., included at least in part in control circuit 100C, including one or more logic circuits configured to generate and/or distribute one or more of the one or more signals φS or instances of signal φ1. In some embodiments, circuit 100 is configured to receive one or more of the one or more signals φS or instances of signal φ1 from a controller external to circuit 100C, e.g., a circuit that includes circuit 100.

In some embodiments, circuit 100 includes the one or more instances of TSD 100TS configured to generate the corresponding instances of signal φ1, e.g., as discussed below with respect to FIG. 2. In some embodiments, circuit 100 includes control circuit 100C configured to generate the corresponding instances of signal φ1, e.g., as discussed below with respect to FIG. 7.

In accordance with the embodiments discussed above, circuit 100 is configured to, in operation, couple a given instance of TSD 100TS and corresponding instance of signal path 100P to current source IS1 and voltage sense circuit 100A through switching circuit 100SW responsive to the one or more signals φS. Circuit 100 is thereby configured to cause current I1 to flow through the parallel arrangement of resistive device R1 and switching device S1 of the given instance of TSD 100TS concurrently with using voltage sensing circuit 100A to detect voltage level V1.

In response to a first logic level of signal φ1, e.g., a high logic level, circuit 100 is configured to, in operation, close switch S1, thereby causing substantially all, e.g., a percentage within a specified tolerance level, of current I1 to flow through switching device S1 such that voltage sensing circuit 100A detects a first instance of voltage level V1 concurrently with switching device S1 being in a closed state.

In response to a second logic level of signal φ1, e.g., a low logic level, circuit 100 is configured to, in operation, open switch S1, thereby causing substantially all of current I1 to flow through resistive device R1 such that voltage sensing circuit 100A detects a second instance of voltage level V1 concurrently with switching device S1 being in an open state.

The order of detecting the instances of voltage level V1 concurrently with switching device SW1 being in the closed and open states is a non-limiting example provided for the purpose of illustration. In some embodiments, e.g., those discussed below with respect to FIGS. 2 and 7, circuit 100 is configured such that the instances of voltage level V1 are detected in a different order.

In some embodiments, e.g., those discussed below with respect to FIGS. 2 and 7, circuit 100 is configured such that, in operation, current I1 flows through the parallel arrangement of resistive device R1 and switching device S1 of the given instance of TSD 100TS in a first direction concurrently with switching device S1 being in the closed state and in a second direction opposite the first direction concurrently with switching device S1 being in the open state.

In embodiments in which circuit 100 is configured to cause current I1 to flow through each of resistors RP1 and RP2, if voltage drops across switching devices, e.g., switching device S1, are assumed to be negligible and set to zero, the first instance of voltage level V1 corresponding to current I1 flowing through switching device S1 is given by:

$$V 1 ( 1 ) = I 1 \times [ R ( RP 1 ) + R ( RP 2 ) ] \qquad ( 1 )$$

where R(RP1) and R(RP2) are the respective resistance values of resistors RP1 and RP2.

In such embodiments, the second instance of voltage level V1 corresponding to current I1 flowing through resistive device R1 is given by:

$$V 1 ( 2 ) = I 1 \times [ R ( R 1 ) + R ( RP 1 ) + R ( RP 2 ) ] \qquad ( 2 )$$

where R(R1) is the resistance value of resistive device R1.

A difference between the first and second instances of voltage level V1 is thereby given as:

$$\begin{matrix}V 1 ( 2 ) - V 1 ( 1 ) = I 1 \times [ R ( R 1 ) + R ( RP 1 ) + R ( RP 2 ) ] - \\ I 1 \times [ R ( RP 1 ) + R ( RP 2 ) ] \\ = I 1 \times R ( R 1 )\end{matrix} \qquad ( 3 )$$

In some embodiments, circuit 100 is configured to output signal Dout having first and second values corresponding to the respective first and second instances of voltage level V1. In some embodiments, e.g., those in which control circuit 100C includes a sampling stage such as a sampling stage 200S discussed below with respect to FIGS. 2, 5, and 7, circuit 100 is configured to output signal Dout having a single value corresponding to the difference between the first and second instances of voltage level V1.

Circuit 100 is thereby configured to output signal Dout based on the difference between the first and second instances of voltage level V1 canceling out resistance values R(RP1) and R(RP2) for the corresponding instance of signal path 100P such that the resultant voltage difference depends solely on the level of current I1 and resistance value R(R1).

Because resistance value R(R1) is temperature sensitive, the resultant voltage difference thereby represents a temperature of resistive device R1 further based on the level of current I1. In some embodiments, the temperature of resistive device R1 is calculated based on the level of current I1 being a predetermined level. In some embodiments, e.g., those discussed below with respect to FIGS. 2, 3, and 7, circuit 100 includes a calibration resistor and circuit 100 is configured such that the temperature of resistive device R1 is calculated further based on a resistance value of the calibration resistor instead of the level of current I1 by using the calibration resistor to cancel out the level of current I1.

Circuit 100 is thereby configured to output signal Dout including an accurate representation of the temperature of resistive device R1 of a given instance of TSD 100TS, in some embodiments improved by including a calibration resistor. Circuit 100 is thereby capable of providing remote temperature measurements of one or more targets, e.g., hot spots, close to the one or more instances of TSD 100TS while offsetting the effects of signal path parasitic resistance with reduced complexity compared to other approaches, e.g., those based on beta-dependent bipolar devices or four-terminal Kelvin sensing arrangements.

In some embodiments in which the one or more instances of signal path 100P do not include resistor RP2, circuit 100 is configured to cause current I1 to flow through resistor RP1 to the corresponding reference voltage node of the corresponding instance of TSD 100TS. By assuming a negligible reference voltage offset between the TSD 100TS and control circuit 100C reference voltage nodes, equations (1) and (2) apply for the case in which resistance value R(RP2) is set to zero, and the resultant voltage difference of equation (3) is unchanged compared to the embodiments discussed above.

Because the reference voltage offset is not necessarily negligible, the accuracy of a temperature determined from the resultant voltage difference is potentially decreased. Thus, such embodiments represent a trade-off between the potential temperature measurement accuracy and reduced complexity and space requirements realized by the one or more instances of signal path 100P including a single resistor RP1 instead of both resistors RP1 and RP2.

FIG. 2 is a schematic diagram of temperature sensor circuit 200, a non-limiting example of circuit 100, in accordance with some embodiments. In some embodiments, temperature sensor circuit 200 is referred to as RTSEN 200, circuit 200, or IC 200.

Circuit 200 includes an instance of a TSD 200TS, a corresponding instance of signal path 100P, discussed above with respect to FIGS. 1A and 1B, and a control circuit 200C. TSD 200TS and control circuit 200C are non-limiting examples of TSD 100TS and control circuit 100C, respectively, each discussed above with respect to FIGS. 1A and 1B.

TSD 200TS includes resistive device R1 and switching device S1 coupled in parallel between terminals T1 and T2, each discussed above with respect to FIGS. 1A and 1B, and a comparator CP1, discussed below.

Control circuit 200C includes current source IS1 and voltage sensing circuit 100A, each discussed above with respect to FIGS. 1A and 1B, a switching circuit 200SW, a non-limiting example of switching circuit 100SW discussed above with respect to FIGS. 1A and 1B, a calibration circuit 200L coupled between current source IS1 and an input terminal of switching circuit 200SW, sampling stage 200S coupled between an output terminal of switching circuit 200SW and the input terminal of voltage sensing circuit 100A, and instances of logic devices AND and INV, each discussed below. In some embodiments, control circuit 200C does not include sampling stage 200S, and the output terminal of switching circuit 200SW is coupled directly to the input terminal of voltage sensing circuit 100A.

In the embodiment depicted in FIG. 2, circuit 200 includes single instances of each of TSD 200TS and signal path 100P. In some embodiments, circuit 200 includes one or more additional instances of TSD 200TS and signal path 100P selectively coupled to control circuit 200C, e.g., through one or more transistors or other switching devices (not shown) in switching circuit 200SW.

A comparator, e.g., comparator CP1, is an electronic circuit including two input terminals configured to, in operation, detect voltage levels Vx1 and Vx2, and an output terminal configured to output a signal, e.g., signal φ1 discussed above with respect to FIGS. 1A and 1B, having one of the high or low logic level in response to voltage level Vx1 greater than voltage level Vx2, and having the other of the high or low logic level in response to voltage level Vx2 greater than voltage level Vx1. In some embodiments, a comparator, e.g., comparator CP1, is comparator 400 discussed below with respect to FIG. 4.

Circuit 200 includes comparator CP1 including the input terminals coupled to terminals T1 and T2 of TSD 200TS, thereby configured to, in operation, detect voltage levels Vx1 and Vx2 at respective terminals T1 and T2, and the output terminal coupled to a control terminal of switching device S1, thereby configured to output signal φ1 to switching device S1 responsive to the voltage levels at terminals T1 and T2.

Switching circuit 200SW includes transistors M1 and M2 coupled in series at a node N1 between the input terminal and the reference voltage node, transistors M3 and M4 coupled in series at a node N2 between the input terminal and the reference voltage node, a switching device S2 coupled between node N1 and the output terminal, and a switching device S3 coupled between node N2 and the output terminal. Each of transistors M1 and M3 is a p-type transistor and each of transistors M2 and M4 is an n-type transistor.

In the embodiment depicted in FIG. 2, nodes N1 and N2 are directly coupled to respective resistors RP1 and RP2 of signal path 100P. In some embodiments, e.g., those in which circuit 200 includes more than one instance of TSD 100TS and signal path 100P, nodes N1 and N2 are coupled to respective resistors RP1 and RP2 through one or more switching devices, e.g., transistors (not shown).

Switching circuit 200SW is configured to receive signals φ2, φ2b, φ2d, and φ2bd, non-limiting examples of the one or more signals φS discussed above with respect to FIGS. 1A and 1B. Gates of transistors M1 and M2 are coupled together and configured to receive signal φ2b, gates of transistors M3 and M4 are coupled together and configured to receive signal φ2, switching device S2 includes a control terminal configured to receive signal φ2d, and switching device S3 includes a control terminal configured to receive signal φ2bd.

Sampling stage 200S is an electronic circuit configured to, in operation, receive first and second instances of voltage level V1 in sequence, e.g., as discussed above with respect to FIGS. 1A and 1B, and generate an output voltage Vin having a voltage level based on a difference between the first and second instances of voltage level V1. In some embodiments, sampling stage 200S is sampling stage 500 discussed below with respect to FIG. 5.

Logic devices AND and INV are IC devices configured to, in operation, output a signal by performing predetermined logic functions on received signals. In the embodiment depicted in FIG. 2, logic devices AND and INV are included in control circuit 200C. In some embodiments, some or all of logic devices AND and INV are included in a circuit (not shown) external to circuit 200C, e.g., a controller.

In the embodiment depicted in FIG. 2, the first instance of logic device AND is an AND gate configured to output signal φ2 by performing an AND operation on received signals φ2a and φ0, the second instance of logic device AND is an AND gate configured to output signal φ2b by performing an AND operation on received signals φ2ba and φ0, the first instance of logic device INV is an inverting circuit configured to output signal φ2bd by performing an inverting operation on signal φ2 as gated by signal φ0, and the second instance of logic device INV is an inverting circuit configured to output signal φ2d by performing an inverting operation on signal φ2b as gated by signal φ0.

Signals φ2a and φ2ba are complementary logic signals, and signal φ0 is a logic signal having a complementary signal 0b in some embodiments, e.g., those in which control circuit 200C includes calibration circuit 200L. In some embodiments, signals φ0, φ0b, φ2a, φ2ba, φ2, φ2b, φ2bd, and φ2d have waveforms as discussed below with respect to FIG. 6.

In some embodiments, e.g., those in which control circuit 200C does not include calibration circuit 200L, control circuit 100C does not include signals φ0 and φ0b, and control circuit 100C and/or an external circuit are otherwise configured to distribute signals φ2, φ2b, φ2bd, and φ2d.

In the embodiment depicted in FIG. 2, circuit 200 is configured to operate in first and second phases based on signal φ0 having the high logic level such that current I1 flows to switching circuit 200SW and along respective first current path P1 or second current path P2 in response to signals φ2 and φ2b.

In the first phase, signals φ2a and φ2ab have the respective high and low logic levels, signals φ2 and φ2b have the respective high and low logic levels, and signals φ2bd and φ2d have the respective high and low logic levels. Signals φ2 and φ2b having the respective high and low logic levels causes transistors M1 and M4 to be switched on and transistors M2 and M3 to be switched off. Based on the direction of flow of current I1, voltage level Vx1 at terminal T1 is greater than voltage level Vx2 at terminal T2, thereby causing comparator CP1 to output signal φ1 having the high logic level such that switching device S1 is in an open state and substantially all of current I1 flows through resistive device R1 as discussed above with respect to FIG. 1.

Signals φ2bd and φ2d having the respective high and low logic levels causes switching devices S2 and S3 to be in the respective open and closed states such that node N1 is coupled to the input terminal of sampling stage 200S through switching device S2, thereby causing a voltage level V2 on node N1 to appear as an instance of voltage level V1 at the input terminal of sampling stage 200S or, in embodiments in which sampling stage 200S is not included, at the input terminal of voltage sensing circuit 100A.

Because node N2 is coupled to the reference voltage node local to control circuit 200C, the instance of voltage level V1 generated in the first phase represents the voltage drop due to current I1 flowing through resistive device R1 and resistors RP1 and RP2 and thereby corresponds to voltage level V1(2) of equation (2) discussed above.

In the second phase, signals φ2a and φ2ab have the respective low and high logic levels, signals φ2 and φ2b have the respective low and high logic levels, and signals φ2bd and φ2d have the respective low and high logic levels. Signals φ2 and φ2b having the respective low and high logic levels causes transistors M2 and M3 to be switched on and transistors M1 and M4 to be switched off. Based on the direction of flow of current I1, voltage level Vx2 at terminal T2 is greater than voltage level Vx1 at terminal T1, thereby causing comparator CP1 to output signal φ1 having the low logic level such that switching device S1 is in a closed state and substantially all of current I1 flows through switching device SW1 as discussed above with respect to FIG. 1.

Signals φ2bd and φ2d having the respective low and high logic levels causes switching devices S2 and S3 to be in the respective closed and open states such that node N2 is coupled to the input terminal of sampling stage 200S through switching device S3, thereby causing a voltage level V3 on node N2 to appear as an instance of voltage level V1 at the input terminal of sampling stage 200S or, in embodiments in which sampling stage 200S is not included, at the input terminal of voltage sensing circuit 100A.

Because node N1 is coupled to the reference voltage node local to control circuit 200C, the instance of voltage level V1 generated in the second phase represents the voltage drop due to current I1 flowing through resistors RP1 and RP2 and thereby corresponds to voltage level V1(1) of equation (1) discussed above.

Accordingly, the difference between the instances of voltage level V1 generated in the first and second phases, V1(2)−V1(1), is given by equation (3) as I1×R(R1), as discussed above.

In the embodiment depicted in FIG. 2, control circuit 200C includes sampling stage 200S and is thereby configured to, in operation, output voltage Vin having a voltage level corresponding to the difference at an output terminal coupled to the input terminal of voltage sensing circuit 100A. Voltage sensing circuit 100A includes an ADC and is thereby configured to output signal Dout as a digital signal having a value corresponding to the difference.

In some embodiments, control circuit 200C does not include sampling stage 200S and is thereby configured to, in operation, receive voltage levels V1(2) and V1(1) sequentially at the input terminal of voltage sensing circuit 100A and is thereby configured to output signal Dout as a digital signal having a sequence of values corresponding to voltage levels V1(2) and V1(1).

Circuit 200 is thereby configured as discussed above to be capable of realizing the benefits discussed above with respect to circuit 100.

In the embodiment depicted in FIG. 2, control circuit 200C includes calibration circuit 200L, an electronic circuit including a calibration resistor, e.g., a high precision and/or temperature-insensitive resistive device, coupled to the voltage reference node and configured to, in operation, conduct current I1 in response to signals φ0 and φ0b having the respective low and high logic levels. The calibration resistor has a known resistance value Ry such that current I1 flowing through the calibration resistor generates a voltage drop VC, also referred to as calibration voltage VC in some embodiments, equal to I1×Ry.

Calibration circuit 200L is thereby configured to, in operation, selectively output calibration voltage VC at an output terminal coupled to the input terminal of voltage sensing circuit 100A. In some embodiments, calibration circuit 200L includes calibration circuit 300 including calibration resistor RC discussed below with respect to FIG. 3.

Circuit 200 is configured to operate in a third phase, also referred to as a calibration phase or calibration operation in some embodiments, based on signals φ0 and φ0b having the respective low and high logic levels such that current I1 flows to the calibration resistor instead of switching circuit 200SW.

Signals φ0 and φ0b having the respective low and high logic levels causes each of signals φ2 and φ2b to have the low logic level and each of signals φ2d and φ2bd to have the high logic level, thereby causing each of switching devices S2 and S3 to be in the open state. Signals φ0 and φ0b having the respective low and high logic levels further causes calibration circuit 200L to output calibration voltage VC to voltage sensing circuit 100A.

As discussed above, the difference between the voltage level V1 instances corresponding to the first and second phases is given by current I1×R(R1), where R(R1) is the resistance value of resistive device R1. Thus, a ratio of the voltage level V1 difference to calibration voltage VC is given by

VR=[I1×R(R1)]/(I1×Ry)=R(R1)/Ry (4)

Because ratio VR has a value independent of the actual level of current I1 and instead dependent on resistance value Ry, the accuracy of the measured value R(R1) is capable of being improved based on resistance value Ry being more accurately known than the actual level of current I1. Thus, in embodiments in which control circuit 200C includes calibration circuit 200L, circuit 200 is capable of generating measuring values R(R1) having greater accuracy than in those embodiments in which control circuit 200C does not include calibration circuit 200L.

In the embodiment depicted in FIG. 2, voltage sensing circuit 100A is configured to output signal Dout having a value corresponding to ratio VR, thereby corresponding to value R(R1) as a fraction of the known value Ry of the calibration resistor.

In some embodiments, e.g., those in which control circuit 200C does not include sampling stage 200S, voltage sensing circuit 100A is configured to output signal Dout having a value, e.g., a third value in the sequence of values, corresponding to calibration voltage VC such that ratio VR is calculable from the sequence of values output from voltage sensing circuit 100A.

FIG. 3 is a schematic diagram of calibration circuit 300, in accordance with some embodiments. Calibration circuit 300 is usable as calibration circuit 200L, discussed above with respect to FIG. 2. In addition to calibration circuit 300, FIG. 3 depicts current source IS1 and voltage sensing circuit 100A, each discussed above with respect to FIGS. 1B and 2.

Calibration circuit 300 includes an input terminal coupled to current source IS1, a first output terminal coupled to voltage sensing circuit 100A, and a second output terminal coupled to current paths P1 and P2, e.g., included in switching circuit 200SW discussed above with respect to FIG. 2.

A p-type transistor M5 is coupled between the input terminal and the second output terminal and includes a gate configured to receive signal φ0b. P-type transistors M6 and M7 and a calibration resistor RC (having resistance value Ry) are coupled in series between the input terminal and the reference voltage node. Each of transistors P6 and P7 includes a gate configured to receive signal φ0 and a source/drain terminal coupled to the first output terminal.

In operation, signals φ0 and φ0b having the respective high and low logic levels, e.g., during the first and second phases discussed above with respect to FIG. 2, causes transistor M5 to be in the closed state and transistors M6 and M7 to be in the open state such that current I1 flows from the input terminal to the second output terminal, and the first output terminal is electrically isolated from calibration resistor RC.

Signals φ0 and φ0b having the respective low and high logic levels, e.g., during the third phase discussed above with respect to FIG. 2, causes transistor M5 to be in the open state and transistors M6 and M7 to be in the closed state such that current I1 flows from the input terminal to the reference voltage node through calibration resistor RC, thereby generating calibration voltage VC at the first output terminal having a value equal to I1×Ry.

Calibration circuit 300 is thereby configured to selectively output calibration voltage VC having the value equal to I1×Ry such that a circuit, e.g., circuit 100, 200, or 700 discussed herein with respect to FIGS. 1A-2 and 7, including calibration circuit 300 is capable of realizing the benefits discussed herein with respect to circuits 100, 200, and 700.

Configurations other than those discussed above by which a calibration resistor is used to selectively output calibration voltage VC having the value equal to I1×Ry are within the scope of the present disclosure.

FIG. 4 is a schematic diagram of comparator 400, in accordance with some embodiments. Comparator 400 is usable as comparator CP1, discussed herein with respect to FIGS. 2 and 7.

Comparator 400 includes a first series of transistors M8-M11 and a second series of transistors M12-M15 coupled between a power supply voltage node VDD configured to have a power supply voltage level VDD and the reference voltage node, and a latch circuit L1 including first and second input terminals and first and second output terminals.

The first series of transistors includes p-type transistors M8 and M9 in series with n-type transistors M10 and M11, and the second series of transistors includes p-type transistors M12 and M13 in series with n-type transistors M14 and M15. P-type transistor M8 and n-type transistor M11 of the first series include gates coupled to the first input terminal configured to receive a voltage level Vx1, p-type transistor M12 and n-type transistor M15 of the second series include gates coupled to the second input terminal configured to receive a voltage level Vx2, and p-type transistor M9 and n-type transistor M10 of the first series and p-type transistor M13 and n-type transistor M14 of the second series are configured as inverters cross-coupled between respective transistors M8/M11 and M12/M15.

The first input terminal of the latch circuit is coupled to gates of the transistors M9 and M10 of the inverter of the first series and thereby configured to receive an internal voltage level Vx1p, and the second input terminal of the latch circuit is coupled to gates of transistors M13 and M14 of the inverter of the second series and thereby configured to receive an internal voltage level Vx2p.

In operation, voltage level Vx1 greater than voltage level Vx2 causes the first input terminal of the latch circuit to be coupled to power supply node VDD such that voltage level Vx1p is at or near power supply voltage level VDD and the second input terminal to be coupled to the reference voltage node such that voltage level Vx2p is at or near the reference voltage level, thereby causing latch L1 to output signal φ1 from the first output terminal having the high logic level.

Voltage level Vx2 greater than voltage level Vx1 causes the second input terminal of the latch circuit to be coupled to power supply node VDD such that voltage level Vx2p is at or near power supply voltage level VDD and the first input terminal to be coupled to the reference voltage node such that voltage level Vx1p is at or near the reference voltage level, thereby causing latch L1 to output signal φ1 from the first output terminal having the low logic level.

Comparator 400 is thereby configured to output signal φ1 having the high or low logic level in response to voltage level Vx1 being greater or less than voltage level Vx2 such that a circuit, e.g., circuit 100, 200, or 700 discussed herein with respect to FIGS. 1A-2 and 7, including comparator 400 is capable of realizing the benefits discussed above with respect to circuits 100, 200, and 700.

FIG. 5 is a schematic diagram of sampling stage 500, in accordance with some embodiments. Sampling stage 500 is usable as sampling stage 200S, discussed above with respect to FIG. 2.

Sampling stage 500 includes a first capacitive device C1 coupled in series with switching devices S4 and S5 between an input terminal and an inverting input terminal of an amplifier OP, and a second capacitive device C2 and switching devices S6-S8 coupled between the inverting input terminal and an output terminal of amplifier OP in a configurable feedback arrangement.

Each of switching device S7 and a non-inverting input terminal of amplifier OP is configured to receive a known common mode voltage level Vcm. The input terminal of sampling stage 500 is configured to receive voltage levels Vi and Vj in respective first phase Phase 1 and second phase Phase 2 such that voltage levels Vi and Vj correspond to respective instances V1(2) and V1(1) of voltage level V1 as discussed above with respect to FIGS. 1B and 2.

In operation, prior to receiving voltage levels Vi and Vj, an offset voltage level Vos is received at the input terminal of sampling stage 500 and switching devices S4-S8 are controlled, e.g., by receiving one or more control signals from a controller, to cause a voltage difference (Vcm-Vos) to appear across capacitive device C1. This difference is subtracted from each of voltage levels Vi and Vj such that voltage [Vi−(Vcm−Vos)] appears across capacitive device C1 during Phase 1 and voltage [Vj−(Vcm−Vos)] appears across capacitive device C1 during Phase 2.

During Phase 1, switching devices S6 and S7 are in the closed state and switching device is in the open state, e.g., based on receiving one or more control signals from a controller, such that offset voltage level Vos appears across capacitive device C2 and amplifier OP causes the voltage difference (Vcm−Vos) to appear at the output terminal.

During Phase 2, switching devices S6 and S7 are in the open state and switching device is in the closed state such that amplifier OP causes voltage level Vin, discussed above with respect to FIG. 2, to appear at the output terminal having a value equal to a sum of the difference (Vi−Vj) and voltage level Vcm.

Based on the known value of voltage level Vcm, voltage level Vin is thereby output to the output terminal of amplifier OP representative of the difference (Vi−Vj) and with offset voltage level Vos cancelled out of voltage level Vin.

Sampling stage 500 is thereby configured to output voltage level Vin representative of the difference V1(2) and V1(1) such that a circuit, e.g., circuit 100, 200, or 700 discussed herein with respect to FIGS. 1A-2 and 7, including sampling stage 500 is capable of realizing the benefits discussed above with respect to circuits 100, 200, and 700.

FIG. 6 depicts operating parameters of circuit 100, 200, or 700, in accordance with some embodiments, that provide a non-limiting example of signals used to generate output signal Dout based on the difference between the first and second instances of voltage level V1 canceling out parasitic resistance values R(RP1) and R(RP2) as discussed above. Other signal configurations used to generate output signal Dout based on the difference between the first and second instances of voltage level V1 canceling out parasitic resistance values R(RP1) and R(RP2) are within the scope of the present disclosure.

In the embodiment depicted in FIG. 6, signals φ0 and φ0b have the respective high and low logic levels during the first and second phases Phase 1 and Phase 2 corresponding to generating instances of voltage level V1, and the respective low and high logic levels during the third phase Phase 3 corresponding to calibration and ADC conversion operations causing output signal Dout to have the value corresponding to ratio VR as discussed above with respect to FIG. 2.

During Phase 1, complementary signals φ2a and φ2ba received at the instances of logic devices AND have the respective high and low logic levels, signals φ2 and φ2b received at respective transistors M3 and M1 have the respective high and low logic levels, thereby configuring switching circuit 200SW to route current I1 along current path P1, signals φ2bd and φ2d received at respective switching devices S3 and S2 have the respective high and low logic levels, thereby causing switching device S3 to be in the closed state and switching device S2 to be in the open state such that voltage level V2 is output from switching circuit 200SW, and signal φ1 has the high logic level, thereby causing switching device S1 to be in the open state such that current I1 flows through resistive device R1.

During Phase 2, complementary signals φ2a and φ2ba have the respective low and high logic levels, signals φ2 and φ2b received at respective transistors M3 and M1 have the respective low and high logic levels, thereby configuring switching circuit 200SW to route current I1 along current path P2, signals φ2bd and φ2d received at respective switching devices S3 and S2 have the respective low and high logic levels, thereby causing switching device S2 to be in the closed state and switching device S3 to be in the open state such that voltage level V1 is output from switching circuit 200SW, and signal φ1 has the low logic level, thereby causing switching device S1 to be in the closed state such that current I1 flows through switching device S1.

During Phase 3, complementary signals φ0 and φ0b have the respective low and high logic levels, thereby causing current to flow through the calibration resistor, e.g., calibration resistor RC, and coupling calibration circuit 200L to the input terminal of voltage sensing circuit 100A, and each of signals φ2bd and φ2d received at respective switching devices S3 and S2 has the high logic level, thereby causing each of switching devices S3 and S2 to be in the open state, corresponding to calibration voltage VC being output from calibration circuit 200L.

FIG. 7 is a schematic diagram of temperature sensor circuit 700, a non-limiting example of circuit 100, in accordance with some embodiments. In some embodiments, temperature sensor circuit 700 is referred to as RTSEN 700, circuit 700, or IC 700.

Circuit 700 includes an instance of a TSD 700TS, a corresponding instance of a signal path 700P, and a control circuit 700C. TSD 700TS, signal path 700P, and control circuit 200C are non-limiting examples of TSD 100TS, signal path 100P, and control circuit 100C, respectively, each discussed above with respect to FIGS. 1A and 1B.

With respect to TSD 200TS, signal path 100P, and control circuit 200C, each discussed above with respect to FIGS. 1A-2, TSD 700TS is configured the same as TSD 200TS except that TSD 700TS does not include comparator CP1 and includes an instance of the reference voltage node coupled to terminal T2. Signal path 700P is configured the same as signal path 100P except that signal path 700P does not include resistor RP2. Control circuit 700C is configured the same as control circuit 200C except that control circuit 700C includes a switching circuit 700SW instead of switching circuit 200SW,

Switching circuit 700SW is configured the same as switching circuit 200SW, discussed above with respect to FIG. 2, except that switching circuit 700SW includes comparator CP1 including input terminals coupled to nodes N1 and N2 and the output terminal coupled to the instance of switching device S1 of TSD 700TS though at least one buffer 700B. Also, in contrast to switching circuit 200SW in which nodes N1 and N2 are directly coupled to respective resistors RP1 and RP2, switching circuit 700SW includes switching device S2 coupled between node N1 and resistor RP1 and switching device S3 coupled between node N2 and resistor RP1.

In some embodiments, the at least one buffer 700B includes one or more inverters, buffer circuits, and/or other digital circuits configured to couple the output terminal of comparator CP1 to the instance of switching device S1. In some embodiments, the at least one buffer 700B is referred to as a series of buffer circuits 700B.

Comparator CP1 is thereby configured to output signal φ1 based on voltage levels V2 and V3, and the at least one buffer 700B is configured to propagate signal φ1 from switching circuit 700SW to the instance of switching device S1.

In some embodiments, switching circuit 700SW includes at least one additional transistor or other switching device (not shown) coupled to the output terminal of comparator CP1 such that switching circuit 700SW is configured to selectively propagate signal φ1 to at least one additional instance of switching device S1 included in a corresponding at least one additional instance of each of TSD 700TS and signal path 700P.

Circuit 700 is configured to receive and/or distribute signals φ0, φ0b, φ2, φ2b, φ2d, and φ2bd in the manner discussed above with respect to FIGS. 2-6 such that during the first phase, current I1 is caused to flow through a current path P3 and switching circuit 700SW concurrently outputs voltage level V2 on node N1 as a corresponding instance of voltage level V1, and during the second phase, current I1 is caused to flow through a current path P4 and switching circuit 700SW concurrently outputs voltage level V3 on node N2 as a corresponding instance of voltage level V1.

Circuit 700 is thereby configured to output signal Dout as a digital signal having one or more values corresponding to the difference between the instances of voltage level V1, and in some embodiments voltage level VC, in accordance with the embodiments discussed above with respect to FIGS. 2-6 such that circuit 700 is capable of realizing the benefits discussed above with respect to circuits 100 and 200.

Compared to circuit 200, circuit 700 includes the one or more instances of TSD 700TS and signal path 700P being less complex than the one or more instances of TSD 200TS and signal path 100P, and instead includes an instance of the at least one buffer 700B corresponding to each of the one or more instances of TSD 700TS and signal path 700P.

FIG. 8 is a flowchart of method 800 of operating a circuit, in accordance with some embodiments. Method 800 is usable with a circuit 100, 200, or 700 discussed above with respect to FIGS. 1A-7.

The sequence in which the operations of method 800 are depicted in FIG. 8 is for illustration only; the operations of method 800 are capable of being executed in sequences that differ from that depicted in FIG. 8. In some embodiments, operations in addition to those depicted in FIG. 8 are performed before, between, during, and/or after the operations depicted in FIG. 8. In some embodiments, the operations of method 800 are a subset of a method of operating an IC, e.g., a digital or other circuit such as circuit 100D discussed above with respect to FIGS. 1A and 1B.

At operation 802, a current is conducted through a current path in series with a resistive device concurrently with detecting a first voltage level. Conducting the current includes using a switching circuit, and detecting the first voltage level includes detecting the first voltage level at a first node of the switching circuit.

Conducting the current through the resistive device includes opening a switching device parallel to the resistive device, e.g., conducting current I1 through resistive device R1 by opening switching device S1 as discussed above with respect to FIGS. 1A-7.

At operation 804, the current is conducted through the current path in series with the switching device parallel to the resistive device concurrently with detecting a second voltage level. Conducting the current includes using the switching circuit, and detecting the second voltage level includes detecting the second voltage level at a second node of the switching circuit.

Conducting the current through the switching device includes closing the switching device parallel to the resistive device, e.g., conducting current I1 through switching device S1 parallel to resistive device R1 by closing switching device S1 as discussed above with respect to FIGS. 1A-7.

In some embodiments, using the switching circuit to conduct the current through the current path in each of operations 802 and 804 includes using switching circuit 100SW to conduct current I1 output from current source IS1 through current path RP1 of signal path 100P of circuit 100 as discussed above with respect to FIGS. 1A and 1B.

In some embodiments, using the switching circuit to conduct the current through the current path in each of operations 802 and 804 includes using switching circuit 200SW to conduct current I1 output from current source IS1 through current path RP1 of signal path 100P of circuit 200 as discussed above with respect to FIGS. 2-6.

In some embodiments, using the switching circuit to conduct the current through the current path in each of operations 802 and 804 includes using switching circuit 700SW to conduct current I1 output from current source IS1 through current path RP1 of signal path 700P of circuit 700 as discussed above with respect to FIG. 7.

In some embodiments, opening and closing the switching device in each of operations 802 and 804 includes using a comparator, e.g., using comparator CP1 or comparator 400, to open and close the switching device by outputting a signal, e.g., signal φ1, as discussed above with respect to FIGS. 2-7.

In some embodiments, using the switching circuit to conduct the current through the current path in each of operations 802 and 804 includes using the switching circuit to conduct the current through a second current path, e.g., current path RP2 of signal path 100P as discussed above with respect to FIGS. 1A-6.

In some using the switching circuit to conduct the current through the current path in operations 802 and 804 includes using the switching circuit to conduct the current through the current path in opposite directions as discussed above with respect to FIGS. 2-7.

In some embodiments, detecting the first and second voltage levels at the first and second nodes of the switching circuit in each of operations 802 and 804 includes detecting the first and second voltage levels at nodes of switching circuit 100SW discussed above with respect to FIGS. 1A and 1B, at nodes N1 and N2 of switching circuit 200SW discussed above with respect to FIGS. 2-6, or at nodes N1 and N2 of switching circuit 700SW discussed above with respect to FIG. 7.

In some embodiments, detecting the first and second voltage levels at the first and second nodes of the switching circuit in each of operations 802 and 804 includes closing and opening a first switching device of the switching circuit, e.g., switching device S2 of switching circuit 200SW or 700SW, and opening and closing a second switching device of the switching circuit, e.g., switching device S3 of switching circuit 200SW or 700SW, as discussed above with respect to FIGS. 2-7.

In some embodiments, detecting the first and second voltage levels in each of operations 802 and 804 includes using a voltage sensing circuit, e.g., voltage sensing circuit 100A as discussed above with respect to FIGS. 1A-7. In some embodiments, detecting the first and second voltage levels in each of operations 802 and 804 includes using a sampling stage, e.g., sampling stage 200S or sampling stage 500 as discussed above with respect to FIGS. 1A-7, e.g., by using the sampling stage to generate an input voltage level, e.g., voltage level Vin, based on a difference between the first and second voltage levels.

At operation 806, a signal is output from the voltage sensing circuit based on the first voltage level and the second voltage level. In some embodiments, outputting the signal includes outputting signal Dout as discussed above with respect to FIG. 7.

In some embodiments, outputting the signal includes performing an analog to digital conversion based on the first voltage level and the second voltage level and outputting a digital signal. In some embodiments, outputting the signal includes performing an analog to digital conversion based on the input voltage level received from the sampling stage, e.g., input voltage level Vin discussed above with respect to FIGS. 2-7.

In some embodiments, outputting the signal includes performing a calibration operation and outputting the signal based on a calibration voltage level, e.g., using a calibration circuit such as calibration circuit 200L or calibration circuit 300 to generate calibration voltage VC as discussed above with respect to FIGS. 2-7.

In some embodiments, outputting the signal includes outputting a sequence of signals corresponding to each of the first voltage level, the second voltage level, and in some embodiments, the calibration voltage. In some embodiments, outputting the signal includes outputting one signal based on the first voltage level, the second voltage level, and in some embodiments, the calibration voltage.

At operation 808, in some embodiments, a temperature of the resistive device is determined based on the signal output from the voltage sensing device. Determining the temperature of the resistive device includes determining a resistance value of the resistive device and using a temperature dependence of the resistance value, e.g., a linear relationship, to determine the temperature.

In some embodiments, determining the temperature of the resistive device includes determining the temperature of resistive device R1 discussed above with respect to FIGS. 1A-7. In some embodiments, determining the temperature of the resistive device includes determining the temperature of a plurality of resistive devices, e.g., multiple instances of resistive device R1.

In some embodiments, determining the temperature of the resistive device includes determining the temperature of one or more hot spots of a circuit, e.g., circuit 100D discussed above with respect to FIGS. 1A and 1B. In some embodiments, determining the temperature of the resistive device includes modifying activity of a circuit, e.g., circuit 100D, in response to determining the temperature.

By executing some or all of the operations of method 800, a circuit outputs a signal based on a voltage level solely due to current path parasitic resistance and a voltage level due to a resistive device and the parasitic resistance such that the difference between the two voltage levels can be used to obtain an accurate measurement of the resistance of the resistive device, thereby realizing the benefits discussed above with respect to circuits 100, 200, and 700.

In some embodiments, a circuit includes a parallel arrangement of a resistive device and a switching device, a current path including a first end coupled to a first terminal of the parallel arrangement, a current source configured to output a current, a switching circuit coupled between a second end of the current path and the current source, and a voltage sensing circuit including an output terminal and an input terminal coupled to the switching circuit, wherein the circuit is configured to output a signal at the voltage sensing circuit output terminal based on a first voltage level output from the switching circuit concurrently with the current path conducting the current and the switching device being in an open state and a second voltage level output from the switching circuit concurrently with the current path conducting the current and the switching device being in a closed state. In some embodiments, the voltage sensing circuit includes an ADC coupled to the output terminal. In some embodiments, the circuit includes a sampling stage, wherein the input terminal of the voltage sensing circuit is coupled to the switching circuit through the sampling stage. In some embodiments, the circuit a calibration resistor selectively coupled between the current source and a reference node, wherein the circuit is configured to output the signal at the voltage sensing circuit output terminal further based on a third voltage level at the voltage sensing circuit input terminal concurrently with the calibration resistor conducting the current. In some embodiments, the current path is a first current path, the circuit includes a second current path coupled between a second terminal of the parallel arrangement and the switching circuit, and the circuit is configured to output the signal at the voltage sensing circuit output terminal further based on each of the first voltage level and the second voltage level concurrently with the first current path and the second current path conducting the current. In some embodiments, the circuit is configured to output the signal at the voltage sensing circuit output terminal further based on the first voltage level concurrently with the first current path and the second current path conducting the current in a first direction, and the second voltage level concurrently with the first current path and the second current path conducting the current in a second direction opposite the first direction. In some embodiments, the parallel arrangement includes a comparator circuit including a first input terminal coupled to the first terminal of the parallel arrangement, a second input terminal coupled to the second terminal of the parallel arrangement, and an output terminal coupled to a control terminal of the switching device. In some embodiments, the switching circuit includes a comparator circuit including a first input terminal coupled to a first node of the switching circuit, a second input terminal coupled to a second node of the switching circuit, and an output terminal coupled to a control terminal of the switching device through at least one buffer.

In some embodiments, an IC includes a control circuit including a current source configured to output a current, a voltage sensing circuit including an ADC configured to output a signal, and a switching circuit coupled to the current source and to an input terminal of the voltage sensing circuit, a plurality of TSDs, wherein each TSD of the plurality of TSDs includes a first TSD terminal and a second TSD terminal, a resistive device coupled between the first and second TSD terminals, and a switching device coupled between the first and second TSD terminals, and a plurality of current paths, wherein each current path of the plurality of current paths includes a first end coupled to the first TSD terminal of a corresponding TSD of the plurality of TSDs and a second end coupled to the switching circuit, wherein the control circuit is configured to output the signal from the ADC based on, for each TSD of the plurality of TSDs, a first voltage level output from the switching circuit concurrently with the corresponding current path of the plurality of current paths conducting the current and the corresponding switching device being in an open state, and a second voltage level output from the switching circuit concurrently with the corresponding current path of the plurality of current paths conducting the current and the corresponding switching device being in a closed state. In some embodiments, the control circuit includes a sampling stage, and the switching circuit is coupled to the input terminal of the voltage sensing circuit through the sampling stage. In some embodiments, the control circuit includes a calibration resistor coupled to the switching circuit. In some embodiments, the plurality of current paths is a first plurality of current paths, the IC includes a second plurality of current paths, wherein each current path of the second plurality of current paths includes a third end coupled to the second TSD terminal of a corresponding TSD of the plurality of TSDs and a fourth end coupled to the switching circuit, and the control circuit is configured to output the signal from the ADC further based on each of the first voltage level and the second voltage level concurrently with the corresponding current path of the first plurality of current paths and the corresponding current path of the second plurality of current paths conducting the current. In some embodiments, the control circuit is configured to output the signal from the ADC further based on the first voltage level concurrently with the corresponding current path of the first plurality of current paths and the corresponding current path of the second plurality of current paths conducting the current in a first direction, and the second voltage level concurrently with the corresponding current path of the first plurality of current paths and the corresponding current path of the second plurality of current paths conducting the current in a second direction opposite the first direction. In some embodiments, each TSD of the plurality of TSDs includes a comparator circuit including a first input terminal coupled to the first TSD terminal, a second input terminal coupled to the second TSD terminal, and an output terminal coupled to a control terminal of the switching device. In some embodiments, the IC includes a plurality of series of buffer circuits, wherein each series of buffer circuits of the plurality of series of buffer circuits includes an output terminal coupled to a control terminal of the switching device of a corresponding TSD of the plurality of TSDs and an input terminal coupled to the switching circuit, wherein the control circuit includes a comparator circuit including a first input terminal coupled to a first node of the switching circuit, a second input terminal coupled to a second node of the switching circuit, and an output terminal selectively coupled to the input terminal of each series of buffer circuits of the plurality of series of buffer circuits.

In some embodiments, a method of operating a circuit includes using a switching circuit to conduct a current through a current path in series with a resistive device concurrently with detecting a first voltage level at a first node of the switching circuit coupled to the current path, using the switching circuit to conduct the current through the current path in series with a switching device parallel to the resistive device concurrently with detecting a second voltage level at a second node of the switching circuit coupled to the current path, and outputting a signal from a voltage sensing circuit based on the first voltage level and the second voltage level. In some embodiments, each of using the switching circuit to conduct the current through the current path in series with the resistive device and the using the switching circuit to conduct the current through the current path in series with the switching device includes conducting the current through the current path being a first current path and conducting the current through a second current path, and the resistive device and the switching device are coupled between the first current path and the second current path. In some embodiments, using the switching circuit to conduct the current through the current path in series with the resistive device includes conducting the current through the current path in a first direction, and using the switching circuit to conduct the current through the current path in series with the switching device includes conducting the current through the current path in a second direction opposite the first direction. In some embodiments, detecting the first voltage level and the detecting the second voltage level include using a sampling stage to generate an input voltage level based on a difference between the first and second voltage levels, and outputting the signal from the voltage sensing circuit includes performing an analog to digital conversion based on the input voltage level received from the sampling stage. In some embodiments, outputting the signal from the voltage sensing circuit includes performing the analog to digital conversion further based on a calibration voltage level received from a calibration circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit comprising:
a parallel arrangement of a resistive device and a switching device;
a current path comprising a first end coupled to a first terminal of the parallel arrangement;
a current source configured to output a current;
a switching circuit coupled between a second end of the current path and the current source; and
a voltage sensing circuit comprising an output terminal and an input terminal coupled to the switching circuit,
wherein the circuit is configured to output a signal at the voltage sensing circuit output terminal based on:
a first voltage level output from the switching circuit concurrently with the current path conducting the current and the switching device being in an open state, and
a second voltage level output from the switching circuit concurrently with the current path conducting the current and the switching device being in a closed state.

2. The circuit of claim 1, wherein
the voltage sensing circuit comprises an analog-to-digital converter (ADC) coupled to the output terminal.

3. The circuit of claim 2, further comprising a sampling stage, wherein
the input terminal of the voltage sensing circuit is coupled to the switching circuit through the sampling stage.

4. The circuit of claim 1, further comprising:
a calibration resistor selectively coupled between the current source and a reference node,
wherein the circuit is configured to output the signal at the voltage sensing circuit output terminal further based on a third voltage level at the voltage sensing circuit input terminal concurrently with the calibration resistor conducting the current.

5. The circuit of claim 1, wherein
the current path is a first current path,
the circuit further comprises a second current path coupled between a second terminal of the parallel arrangement and the switching circuit, and
the circuit is configured to output the signal at the voltage sensing circuit output terminal further based on each of the first voltage level and the second voltage level concurrently with the first current path and the second current path conducting the current.

6. The circuit of claim 5, wherein
the circuit is configured to output the signal at the voltage sensing circuit output terminal further based on:
the first voltage level concurrently with the first current path and the second current path conducting the current in a first direction, and
the second voltage level concurrently with the first current path and the second current path conducting the current in a second direction opposite the first direction.

7. The circuit of claim 6, wherein
the parallel arrangement further comprises a comparator circuit comprising:
a first input terminal coupled to the first terminal of the parallel arrangement;
a second input terminal coupled to the second terminal of the parallel arrangement; and
an output terminal coupled to a control terminal of the switching device.

8. The circuit of claim 1, wherein
the switching circuit comprises a comparator circuit comprising:
a first input terminal coupled to a first node of the switching circuit;
a second input terminal coupled to a second node of the switching circuit; and
an output terminal coupled to a control terminal of the switching device through at least one buffer.

9. An integrated circuit (IC) comprising:
a control circuit comprising:
a current source configured to output a current;
a voltage sensing circuit comprising an analog-to-digital converter (ADC) configured to output a signal; and
a switching circuit coupled to the current source and to an input terminal of the voltage sensing circuit;
a plurality of temperature sensing devices (TSDs), wherein each TSD of the plurality of TSDs comprises:
a first TSD terminal and a second TSD terminal;
a resistive device coupled between the first and second TSD terminals; and
a switching device coupled between the first and second TSD terminals; and
a plurality of current paths, wherein each current path of the plurality of current paths comprises a first end coupled to the first TSD terminal of a corresponding TSD of the plurality of TSDs and a second end coupled to the switching circuit,
wherein the control circuit is configured to output the signal from the ADC based on, for each TSD of the plurality of TSDs:
a first voltage level output from the switching circuit concurrently with the corresponding current path of the plurality of current paths conducting the current and the corresponding switching device being in an open state, and
a second voltage level output from the switching circuit concurrently with the corresponding current path of the plurality of current paths conducting the current and the corresponding switching device being in a closed state.

10. The IC of claim 9, wherein
the control circuit further comprises a sampling stage, and
the switching circuit is coupled to the input terminal of the voltage sensing circuit through the sampling stage.

11. The IC of claim 9, wherein
the control circuit further comprises a calibration resistor coupled to the switching circuit.

12. The IC of claim 9, wherein
the plurality of current paths is a first plurality of current paths,
the IC further comprises a second plurality of current paths, wherein each current path of the second plurality of current paths comprises a third end coupled to the second TSD terminal of a corresponding TSD of the plurality of TSDs and a fourth end coupled to the switching circuit, and
the control circuit is configured to output the signal from the ADC further based on each of the first voltage level and the second voltage level concurrently with the corresponding current path of the first plurality of current paths and the corresponding current path of the second plurality of current paths conducting the current.

13. The IC of claim 12, wherein
the control circuit is configured to output the signal from the ADC further based on:
the first voltage level concurrently with the corresponding current path of the first plurality of current paths and the corresponding current path of the second plurality of current paths conducting the current in a first direction, and
the second voltage level concurrently with the corresponding current path of the first plurality of current paths and the corresponding current path of the second plurality of current paths conducting the current in a second direction opposite the first direction.

14. The IC of claim 13, wherein
each TSD of the plurality of TSDs further comprises a comparator circuit comprising:
a first input terminal coupled to the first TSD terminal;
a second input terminal coupled to the second TSD terminal; and
an output terminal coupled to a control terminal of the switching device.

15. The IC of claim 9, further comprising:
a plurality of series of buffer circuits, wherein each series of buffer circuits of the plurality of series of buffer circuits comprises an output terminal coupled to a control terminal of the switching device of a corresponding TSD of the plurality of TSDs and an input terminal coupled to the switching circuit,
wherein the control circuit further comprises a comparator circuit comprising:
a first input terminal coupled to a first node of the switching circuit;
a second input terminal coupled to a second node of the switching circuit; and
an output terminal selectively coupled to the input terminal of each series of buffer circuits of the plurality of series of buffer circuits.

16. A method of operating a circuit, the method comprising:
using a switching circuit to conduct a current through a current path in series with a resistive device concurrently with detecting a first voltage level at a first node of the switching circuit coupled to the current path;
using the switching circuit to conduct the current through the current path in series with a switching device parallel to the resistive device concurrently with detecting a second voltage level at a second node of the switching circuit coupled to the current path; and
outputting a signal from a voltage sensing circuit based on the first voltage level and the second voltage level.

17. The method of claim 16, wherein
each of the using the switching circuit to conduct the current through the current path in series with the resistive device and the using the switching circuit to conduct the current through the current path in series with the switching device comprises:
conducting the current through the current path being a first current path; and
conducting the current through a second current path, and
the resistive device and the switching device are coupled between the first current path and the second current path.

18. The method of claim 16, wherein
the using the switching circuit to conduct the current through the current path in series with the resistive device comprises conducting the current through the current path in a first direction, and
the using the switching circuit to conduct the current through the current path in series with the switching device comprises conducting the current through the current path in a second direction opposite the first direction.

19. The method of claim 16, wherein
the detecting the first voltage level and the detecting the second voltage level comprise using a sampling stage to generate an input voltage level based on a difference between the first and second voltage levels, and
the outputting the signal from the voltage sensing circuit comprises performing an analog to digital conversion based on the input voltage level received from the sampling stage.

20. The method of claim 19, wherein
the outputting the signal from the voltage sensing circuit comprises performing the analog to digital conversion further based on a calibration voltage level received from a calibration circuit.
